(19) United States
(12) Patent Application Publication
(10) Pub. No.: US 2010/0239762 A1
(43) Pub. Date: Sep. 23, 2010

(54) PROCESS AND APPARATUS FOR THE INTRODUCTION AND REMOVAL OF A SUBSTRATE INTO AND FROM A VACUUM COATING UNIT

(75) Inventors: Dietmar Schulze, Dresden (DE); Hans-Christian Hecht, Weinboehla (DE); Jochen Krause, Dresden (DE); Michael Hofmann, Dresden (DE)

Correspondence Address: HESLIN ROTHENBERG FARLEY & MESITI PC, 5 COLUMBIA CIRCLE, ALBANY, NY, 12203, US

(73) Assignee: VON ARDENNE Anlagentechnik GmbH, Dresden (DE)

(21) Appl. No.: 12/665,953

(22) PCT Filed: Jun. 23, 2008
(86) PCT No.: PCT/EP2008/057969

§ 371 Date: May 13, 2010

(30) Foreign Application Priority Data
Jun. 22, 2007 (DE) 10 2007 029 286.6

(51) Int. Cl. B05D 1/00; C23C 14/56

(52) U.S. Cl. 427/294; 118/50

(57) ABSTRACT

An apparatus is provided for introduction and/or removal of a substrate into and/or from a process chamber of a vacuum coating unit that includes a process region adjoined by a lock chamber separable from surrounding atmosphere and from the process region by vacuum-tight lock gates. The process region encompasses a process chamber and a transfer chamber for altering transport speed. A vacuum-tight gate on the inlet side of a lock system is opened, the substrate is transported into the lock system and the gate is closed. Pressure in the lock system is subsequently matched to pressure in a subsequent space. An outlet-side gate of the lock system is opened and the substrate is transported from the lock system. The lock system includes a lock chamber and the adjoining transfer chamber. A passage between the transfer chamber and lock chamber remains open during introduction or removal of the substrate.

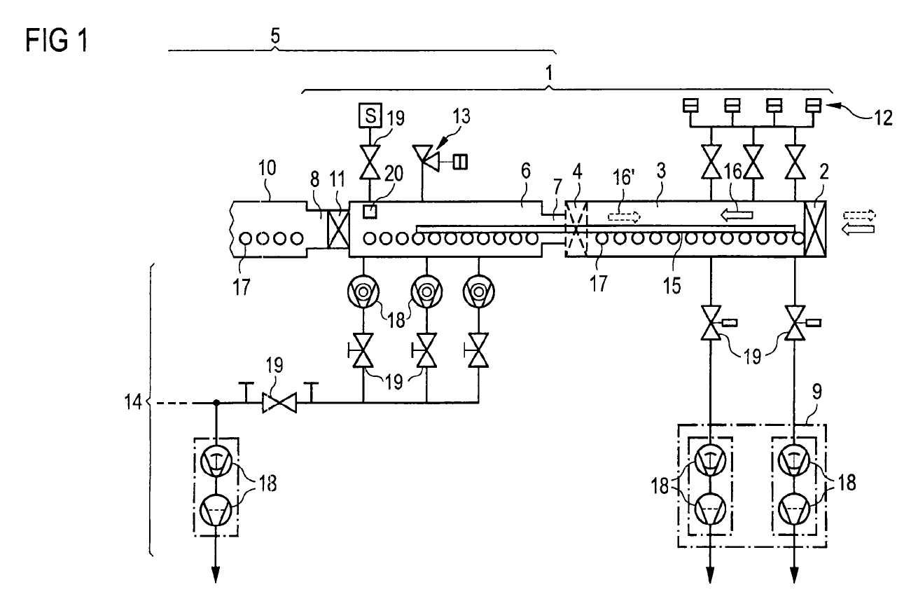

The present invention relates to a process for the inward and outward transfer of a substrate into or from a process chamber of a vacuum-coating plant, in which a process region is adjoined by a lock chamber, which can be separated from the surrounding atmosphere and from the process region by two lock gates, which can be closed in a vacuum-tight manner, and the process region comprises at least one process chamber and also a transfer chamber in the region adjoining the lock chamber, which transfer chamber is intended for altering the transport speed of the substrate, in which process, a vacuum-tight gate located on the inlet side of a lock system, when seen in the substrate transport direction, is opened for the inward and outward transfer of a substrate, an outlet-side gate of the lock system being closed in a vacuum-tight manner, the substrate is then transported into the lock system and the gate is closed, the pressure in the lock system is subsequently adapted to the pressure in the space which follows in the transport direction, an outlet-side gate at the end of the lock system is then opened and the substrate is transported from the lock system

The invention likewise relates to lock systems intended for carrying out the inward and outward transfer of the substrate.

Lock systems of this kind can be used in various dimensions for vacuum-coating plants in industrial applications, particularly in plants used for coating flat substrates such as architectural glass, plastic or metal substrates, substrates for displays, silicon wafers etc. in a through-feed process.

So-called three-chamber vacuum-coating plants comprise, in addition to the two lock chambers for the inward and outward transfer of the substrates, a process region comprising at least one process chamber, and a transport device by means of which substrates can be moved through the vacuum system along a transport path. The process region comprises a transfer chamber that is frequently located on the inlet side. At least one, usually several consecutive process chambers are connected to the transfer chamber, when viewed in the direction of transport, depending on the layer or layer system to be applied. An outlet-side transfer chamber is connected to the process chambers.

These process chambers are universally known as “functional chambers” or so-called “compartments.” Coating compartments, that is to say, process chambers in which the substrates are coated, and pumping compartments, that is to say, process chambers, which serve for the evacuation of individual coating compartments or the gas separation between coating compartments, often alternate along the transport path. Depending on the layer system to be produced, it is also possible to arrange additional process chambers for carrying out additional process steps, for example, for temperature control or heat treatment, cleaning, passivation or activation of a substrate surface etc. There can also be a change in the order of the consecutive compartments. The individual compartments are interconnected via openings through which the substrate is guided from one compartment into the next.

The lock chambers can be separated in relation to the surrounding atmosphere using vacuum technology with the aid of plant gates, which can be closed in a vacuum-tight manner and are disposed at the inlet and outlet of the vacuum-coating plant. Inside the vacuum-coating plant, both lock chambers can be separated from the adjoining process region in a vacuum-tight manner with the aid of intermediate gates. These intermediate gates will be referred to below as “lock-inlet gate” and “lock-outlet gate” in accordance with their function as inlet or outlet during the process of transporting a substrate through the individual chambers. The gate disposed between the inlet lock chamber and the process region is thus the lock-outlet gate of the inward transfer, and the gate disposed between the process region and the outlet lock chamber is the lock-inlet gate of the outward transfer.

In continuously operating coating plants, an intermediate gate disposed between the lock chamber and the process region is adjoined by a section of the plant, a so-called “transfer region,” in which the transport speed of the substrates is adapted from the discontinuous transfer speed to the continuous process speed. For this purpose, transfer regions each comprise a transport device, which comprise sections having separate drives, a so-called passing band, in order to adapt the transport speed from the feed speed used in the front part of the transfer chamber to the process speed used during the coating process or vice versa.

The transfer chamber comprises narrow openings on one or both sides, an entry opening and/or an exit opening, through which the substrates can be moved into and out of the transfer chamber. Due to this open passage to the adjacent compartment, the continuous substrate transport adjusted in the transfer chamber can be continued in the adjacent compartment. The term “chamber” here refers to a delimitable volume defined by an independent housing or by partition walls disposed consequently in the transport direction inside a larger housing of the vacuum-coating plant. The housing or partition walls comprise entry and exit openings described above for transporting the substrate though the plant. The term “chamber” can also be meant to connote that the individual volumes are closed in a vacuum-tight manner, but this is not a requisite. A transfer chamber of a vacuum-coating plant is described in DE 10 2005 024 180 A1 by way of example.

The openings of a transfer chamber serving for transporting the substrate are formed such that it is not possible to carry out a pressure equalization between the transfer chamber and the adjoining compartment by way of this open passage alone. These openings can be formed as slit diaphragms, for example. When leaving the transfer chamber, the substrate enters via the exit opening into the compartment, which adjoins the transfer chamber and can be a pumping compartment or a coating compartment, and is then treated.

Since the front end of the transfer chamber is open in relation to the vacuum atmosphere of the upstream lock chamber by virtue of the entry opening, when the intermediate gate is open for the introduction of a substrate, and since the rear end of the transfer chamber is open in relation to the following compartment by virtue of the exit opening, the pressure gradient between the pressure prevailing at the entry opening and the high vacuum prevailing at the exit opening must be maintained inside the transfer chamber in order to enable a high-vacuum process in the compartments adjoining the transfer chamber. Since the same requirements apply with respect to the adjustment of the transport regime and maintenance of the process vacuum at the end of the process region as at the start of the process region, but in reverse direction, a transfer chamber is likewise disposed at the end of the process region and before the lock chamber serving for the outward transfer of the substrate.

For maintaining the pressure gradient in a transfer chamber, the interior of the same is likewise evacuated, mostly incrementally using several vacuum pumps disposed along the transport chamber. In the coating plant described in DE 10 2004 008 598 A1, vacuum pumps are disposed for this purpose in the first and the second thirds of the inlet-side transfer chamber. These vacuum pumps lower the pressure in the transfer chamber in two stages. The last third of the transfer chamber is evacuated by an additional vacuum pump. This third serves as a pump compartment in DE 0 2004 008 598 A1 and performs the task of implementing a gas separation between the transfer chamber and the first coating compartment by simultaneously evacuating both the third of the transfer chamber and the coating compartment adjoining the pump compartment.

In this way, the overall length of the vacuum-coating plant has been reduced by at least one pump compartment. However, the length of a vacuum-coating plant is basically determined by the size of the substrates since a substrate or a plurality of substrates has to fit in each chamber of the lock systems and in each compartment. Particularly in the case of large-area substrates, this results in very long and inflexible plants in which each additional chamber entails elaborate and expensive additions to plant and equipment. The prior-art vacuum-coating plants used for flat glass are thus usually adapted to the prevalent dimensions of the glass panes in the sizes of 6000 mm×3210 mm, approximately 100″×126″ (2540 mm×3210 mm) or 100″×144″ (2540 mm×3658 mm), as a result of which the coating process is confined to substrates of this size.

In DE 10 2004 008 598 A1, for reducing the overall length of a vacuum-coating plant, a so-called five-chamber plant is used as a three-chamber plant by leaving open the intermediate gate between a lock chamber and the adjacent buffer chamber, which is disposed before the process region and which reduces the cycle times of the plant. Consequently, substrates of a size exceeding the length of the lock chamber can be treated in this plant. While a lock chamber in a three-chamber plant adapts the pressure to the inlet-side atmospheric pressure and the outlet-side process vacuum, the buffer chamber is interconnected in the five-chamber plant. This buffer chamber integrates an additional pressure stage and reduces the pressure difference between the inlet and the outlet of a lock chamber so that the pumping times can be reduced clearly.

However, five-chamber plants generally represent high expenditure in terms of equipment and consequently also energy, particularly in the case of the substrate sizes cited above. In the use of a five-chamber plant as a three-chamber plant described in DE 10 2004 008 598 A1, the expenditure in terms of time and energy is increased disproportionately since twice the chamber size, of the lock and buffer chamber jointly, has to be evacuated for each inward and outward transfer process from the atmospheric pressure up to almost a process vacuum, even in the case of marginally larger substrates.

It is therefore the object of the present invention to specify a vacuum-coating plant comprising a transfer chamber disposed at the inlet side or outlet side or both sides and requiring less installation space, which vacuum-coating plant is suitable for flexibly coating even substrates, the length of which exceeds that of a lock chamber.

The invention will be described below mainly on the basis of the example of the inward transfer of a substrate with the aid of the transfer chamber disposed at the inlet side. The outward transfer process is similar thereto.

The process for the inward and outward transfer of a substrate in accordance with claim 1 and the lock system used for this purpose in accordance with claim 10 make it possible, even in three-chamber plants, to transfer substrates into a vacuum-coating plant through an interlock and to transfer them out of the same through an interlock, the length of the substrates exceeding that of a lock chamber. By means of an additional lock valve disposed at the end of the inlet-side transfer chamber or at the start of the outlet-side transfer chamber and the lock gate, which remains open and which functions as an intermediate gate described above, in a standard operation of the three-chamber plant, the inward transfer and/or the outward transfer processes are extended by a region, which is assigned to the process region in a manner specific to the plant in terms of vacuum and transport mode, and by the length of the respective adjoining transfer chamber.

This additional lock valve, which is designed to be vacuum-tight, seals the lock system in its extended mode in relation to the adjoining process chamber in the same way as a lock gate seals the lock system in the normal mode, that is to say, when coating substrates that are shorter than the length of the lock chamber. The term “lock valve” is used here to merely distinguish between the concepts. The lock gate and the lock valve may differ in terms of their construction or function, but this difference is not included in the different terms.

The integration of the lock valve further enables the use of the vacuum-coating plant with the described lock system in the case of normal substrate sizes and constantly open lock valve in the traditional three-chamber operation, in which the transfer region is separated from a process chamber by way of one opening only. Such a lock valve can also be integrated in existing plants if such an integration is allowed for by the construction of the vacuum-coating plant, e.g. as a modular, retrofittable plant.

The assignment of the transfer chamber to the lock system has an influence on the process region in terms of the cycle times. Firstly, a larger volume used for the inward and outward transfer process must be evacuated and aerated; secondly the process chambers adjoining the lock system are discontinuously occupied with substrates and freed therefrom.

The extension of the pumping times and aeration times as a result of the combined, increased volume of the lock system can be dealt with, for example, by means of the pumping power or a special pump regime and, in the case of aeration, by means of appropriately dimensioned aerating units. The pump regime or aeration regime coordinates the power, vacuum range and, depending thereon, the activation of the pumps or valves with each other in one embodiment of the process and the lock system used for this process where both the lock chamber and the transfer chamber are provided with pumps, and at least the lock chamber is provided with an aerating unit, which pumps and aerating units are used for adjusting the pressure in the volume of the lock system. Due to the pressures to be adjusted for the lock chamber and the transfer chamber during standard operation of such a vacuum-coating plant and due to the pumps and aerating unit configured for this purpose, these components can frequently also be used for the inward/outward transfer and coating of excessively long substrates.

An improvement in the effectiveness of the operation of vacuum-coating plants is further possible if a pressure gradient is adjusted in the combined volume. According to an embodiment of the lock system, this is possible via an entry opening during inward transfer or an exit opening during outward transfer. These openings represent a reduction in the cross-section of the transfer chamber, when viewed in the transport direction, at least at that end of the transfer chamber that adjoins the lock chamber. Such a continuous opening ensures the transport of the substrate through the lock system, but it reduces the pressure equalization between the transfer chamber and the lock chamber in such a way that a pressure gradient can be built up between the two chambers. This gradient has a lower pressure toward the process chamber, and a higher pressure toward the plant gate so that the evacuation is accelerated and the cycle times can be reduced.

In one embodiment, described above, comprising separate pumps and/or aerating units for both or one chamber of a lock system, such a gradient can be adjusted and maintained in a targeted manner. It is thus possible in one embodiment of the process, to also assign an aerating system to the transfer chamber in addition to the aerating system of the lock chamber, which aerating system is selectively activated or deactivated for accelerating the aeration process or for the targeted adjustment of a pressure gradient.

In one embodiment of the process, it is also possible to adjust uniform pressure in the lock and transfer chambers depending on the cycle times desired, the pressures to be generated and other process or plant parameters. This is possible both by way of pressure equalization between the two chambers or optionally the active assistance of the pumping system(s) or aerating units.

In another embodiment of the process, the pressure is adapted in the entire lock system or—if a pressure gradient is to be produced—in one region of the lock system to the pressure adjusted in the chamber, through which the substrate will pass after the lock system. Depending on the layer system to be produced, this chamber can be a coating compartment, for example, or any other compartment used for pre-treatment or intermediate treatment. In the case of pressure adaptation carried out in certain regions, the pressure is adapted in that region of the lock system that adjoins the subsequent compartment.

As a result of the pressure adaptation by means of a gas inlet disposed optionally in addition to the pumping system in this region, the pressure and the composition of residual gas can be adapted to the conditions in the subsequent chamber. For adapting the gas composition, a further embodiment of the process provides for the admission of gas into the lock system, which gas is also used in the subsequent chamber as process gas. These measures prevent the escape of process gas atmosphere into the subsequent chamber or the entry of gas from there into the chamber and a disturbance of the process gas atmosphere in this chamber, when the gate separating the lock system and the subsequent chamber is opened. The pressure adaptation also enables the setting of almost equal conditions on both sides of the gate for the substrate partial pressure and additionally also for the process gas pressure. The term “process gas” refers to gas admitted into a chamber for carrying out a coating or treatment process of the substrate.

Even if the inward transfer or the outward transfer are carried out discontinuously between the lock system and the adjoining process chamber due to the additional lock valve, the required switchover of the transport mode from or to the continuous coating operation can take place in the transfer chamber even in the inward/outward transfer process claimed. For this purpose, the separate drive of the continuous transport is switched on or off when the lock valve has been opened.

The invention will be explained in more detail below with reference to an exemplary embodiment of a lock system for the inward transfer of a substrate into a vacuum-coating plant. The FIGURE shows a lock system 1, as claimed by claim 10, for the inward transfer of a substrate 15 into a vacuum-coating plant, the length of the substrate exceeding that of the lock chamber 3. In place of a long substrate, a plurality of smaller substrates can also be transferred similarly through an interlock lock into and out of the vacuum-coating plant. The lock system 1 represents a part of this vacuum-coating plant and comprises chambers and chamber regions, as is known to be the case in three-chamber vacuum-coating plants. The outward transfer of the substrate and the lock system required for the same essentially correspond to the illustrated system, but in reverse order. As a result, the outward transfer also occurs in reverse order. This is illustrated by the arrow marked in dashed lines for the transport direction 16′ and the direction in which the substrate 15 is discharged from the lock system.

The lock system 1 shown in the FIGURE comprises a lock chamber 3, referred to as “inlet lock chamber 3” for the inward transfer process described. The inlet lock chamber 3 can be separated from the surrounding atmosphere by a plant gate 2 that can be closed in a vacuum-tight manner. The plant gate 2 serves as the entry to the vacuum-coating plant. The process region 5, whose region adjoining the inlet lock chamber 3 is formed as a transfer chamber 6—the first transfer chamber 6 in the example of inward transfer described—is connected to the inlet lock chamber 3. The process region 5 and the inlet lock chamber 3 can be separated from each other by a lock-outlet gate 4 using vacuum technology.

A transport device 17 is located in the individual chambers of the vacuum-coating plant for transporting the substrate 15 through the lock system and through the entire vacuum-coating plant. The transfer chamber 6 comprises an entry opening 7 and an exit opening 8. The transfer chamber 6 is adjoined by a process chamber 10, which, depending only on the layer or layer sequence to be applied or as a sequence of coating or pump compartments, forms that part of the vacuum-coating plant in which the substrate 15 is treated and coated and that is connected to the transfer chamber 6 via the exit opening 8. A lock valve 11, e.g. a flap valve, which is an additional component in comparison with the three-chamber units known from the prior art, is disposed in the exit opening 8 so that the process chamber 10 can be separated from the transfer chamber 6 using vacuum technology in such a way that the process vacuum in the process chamber 10 can be maintained even at atmospheric pressure in the transfer chamber 6. Alternately, other valves or gates can also be used that can perform the function described.

For the inward transfer of a substrate 15 through the plant gate 2, which simultaneously acts as the lock-inlet gate 2 of the inlet lock chamber 3, into a vacuum-coating plant, the transfer chamber 6 and the inlet lock chamber 3 are separated from the process chamber 10 with the aid of the lock valve 11 in a vacuum-tight manner. The lock-outlet gate 4 of the inlet lock chamber 3 is open. After closing the lock valve 11, the lock system 1 is aerated with the aid of a first aerating unit 12 of the inlet lock chamber 3 that is alternately also supplemented by an additional aerating unit 13 of the transfer chamber 6. The plant gate 2 is then opened. The substrate 15 can be transported with the aid of the transport system 17 into the lock system 1. Due to the lock-outlet gate 4 that is open during the entire inward transfer process, it is also possible to introduce a substrate 15, the length of which exceeds that of the inlet lock chamber 3.

In order to effectively prevent the process chamber 10 from being damaged or at least contaminated, the opening of the plant gate 2 is coupled to the lock valve 11 in such a way that the plant gate 2 can be opened in relation to the surrounding atmosphere only if the lock valve 11 has been closed beforehand. Additionally, the lock-outlet gate 4 can also be opened forcibly during the entire inward/outward transfer process for substrates that are excessively long for said process in order to effectively prevent the substrate 15 from being damaged.

The atmospheric pressure in the inlet lock chamber 3 can be lowered after closing the plant gate 2 from approximately 1000 mbar to a fine vacuum of approximately 10⁻³ mbar with the aid of a first pumping system 9, which comprises, e.g. a number of stacked pumps 18, that is to say, pumps connected in series such as Roots pumps together with rotary vane pumps. The pumps 18 can be connected to or separated from the inlet lock chamber 3 with the aid of valves 19.

Pumps 18 and valves 19 of additional pumping systems 14 are connected in the front, central and rear regions of the transfer chamber 6. These pumps and valves incrementally evacuate the transfer chamber 6 to a final transfer temperature after a primary pressure generated by the first pumping system 9 is reached. This final transfer temperature mostly lies close to the process vacuum prevailing in the process chamber 10. The additional pumping system 14 in the transfer chamber 6 is usually a multi-stage high-vacuum system comprising valves 19, e.g. booster pumps and turbo-molecular pumps, with the aid of which a high-vacuum pressure of approximately 10⁻⁴ mbar or below can be produced in the transfer chamber 6.

That region of the transfer chamber 6 that adjoins the lock valve 11 is provided with a gas inlet 20, through which process gas fed from a source S can be admitted into this region of the transfer chamber 6 such that this process gas can be controlled or regulated using valves 19.

The pressures and pumps mentioned above are merely cited by way of example. Depending on the coating process to be carried out, it is also possible to adjust varying pressures in the process chamber and consequently also in the lock system, and to use other pumps. Numerous configurations of single-stage or multi-stage pumping systems are available to the person skilled in the art for the various vacuum ranges and the evacuation times to be achieved.

The substrate is then supplied through the open lock valve 11 to the subsequent process chamber 10. After the substrate has passed the process region, its outward transfer is carried out in an analogous, reverse order with the aid of an additional lock system 1 until the atmospheric pressure is reached. This lock system 1 is also formed by the lock chamber 3, namely the outlet lock chamber connected to an upstream transfer chamber 6 in that the lock-inlet gate 4 between the outlet lock chamber 3 and the transfer chamber 6 remains open during the entire outward transfer process and the lock system 1 can be separated from an adjoining process chamber 10 with the aid of an additional lock valve 11.

### Process and Apparatus for the Inward and Outward Transfer of a Substrate into And from a Vacuum-Coating Plant

### LIST OF REFERENCE NUMERALS

1 Lock system
2 Plant gate, lock-inlet gate
3 Lock chamber, inlet lock chamber, outlet lock chamber
4 Lock-outlet gate, lock-inlet gate
5 Process region
6 Transfer chamber, first transfer chamber
7 Entry opening
8 Exit opening
9 First pumping system
10 Process chamber, compartment
11 Lock valve
12 First aerating unit
13 Additional aerating unit
14 Additional pumping system
15 Substrate
16 Transport direction of inward transfer
16′ Transport direction of outward transfer
17 Transport device
18 Pump
19 Valve
20 Gas inlet
S Process gas source

1. A process for inward and/or outward transfer of a substrate into and/or from a vacuum-coating plant, in which a process region is adjoined by a lock chamber, the lock chamber being selectively separated from surrounding atmosphere and from the process region by two lock gates that can be closed in a vacuum-tight manner, and the process region comprises at least one process chamber and also a transfer chamber in a region adjoining the lock chamber, said transfer chamber being adapted for altering transport speed of the substrate, wherein a vacuum-tight gate located on an inlet side of a lock system, when seen in a substrate transport direction, is opened for the inward and/or outward transfer of the substrate, an outlet-side gate of the lock system being closed in a vacuum-tight manner, the substrate is then transported into the lock system and the inlet side gate is closed, pressure in the lock system is subsequently adapted to a pressure in a space which follows in the transport direction, the outlet-side gate at an end of the lock system is then opened and the substrate is transported from the lock system, the lock system comprising the lock chamber and a lock valve that closes the transfer chamber in relation to the adjoining process chamber in a vacuum-tight manner,
the transfer chamber being connected to the lock chamber, and the lock gate between the transfer chamber and the lock chamber remaining open during the inward and outward transfer of the substrate as long as a substrate is present in the lock chamber.

2. A process for operating a vacuum-coating plant having an inlet lock chamber, a process region and an outlet lock chamber, disposed one after an other in a transport direction of a substrate and separable from each other in a vacuum-tight manner by lock gates, a first transfer chamber of the process region adjoining the inlet lock chamber, and a second transfer chamber of the process region adjoining the outlet lock chamber, inward transfer of the substrate into the vacuum-coating plant being carried out with aid of a lock system, the substrate being coated in the process chambers of said vacuum-coating plant, and outward transfer of the substrate from the vacuum-coating plant being carried out with aid of a lock system, wherein the inward transfer and/or outward transfer of the substrate are effected by the process as claimed in claim 1.

3. The process according to claim 1, wherein pressure in a combined volume formed by the lock chamber and the transfer chamber is lowered by a pumping system of the lock chamber and a pumping system of the transfer chamber.

4. The process according to claim 1, wherein a pressure gradient is adjusted between the lock chamber and the transfer chamber.

5. The process according to claim 1, wherein a gas inlet in an outlet-side region of the transfer chamber is used to adapt pressure in at least said region of the lock system to pressure prevailing in a chamber following in the transport direction.

6. The process according to claim 5 wherein for adapting the pressure in at least said region of the lock system, a process gas used for a process in the chamber following in the transport direction is admitted through the gas inlet.

7. The process according to claim 1, wherein a combined volume formed by the lock chamber and the transfer chamber is aerated by an aerating unit of the lock chamber.

8. The process according to claim 7 wherein aeration of the combined volume with the aid of the aerating unit of the lock chamber is optionally supplemented by an additional aerating unit connected to the transfer chamber.

9. The process according to claim 1, wherein pressure conditions between the lock chamber and the transfer chamber, both of which form a combined volume when the lock gate is open, are adapted to each other.

10. The process according to claim 1, wherein the transport of the substrate is altered in the transfer chamber from discontinuous to continuous or vice versa.

11. The process according claim 1, wherein opening of a lock gate of the lock chamber on at side of the lock chamber oriented away from the transfer chamber is coupled to vacuum-tight closure of the lock valve of the transfer chamber.

12. A lock system for inward and/or outward transfer of a substrate into and/or from a vacuum-coating plant, in which a process region is adjoined by a lock chamber separable from surrounding atmosphere and from the process region by two lock gates that can each be closed in a vacuum-tight manner, and the process region comprises at least one process chamber and also a transfer chamber in a region adjoining the lock chamber, the transfer chamber being adapted for altering transport speed of the substrate, said lock system comprising the lock chamber with a lock gate that can be closed in relation to the surrounding atmosphere, the transfer chamber including a lock valve that closes the transfer chamber in relation to the adjoining process chamber of the process region in a vacuum-tight manner, and an open passage disposed between the lock chamber and the transfer chamber.

13. The lock system according to claim 12 wherein the open passage is formed by an open lock gate of the lock chamber.

14. The lock system according to claim 12 further comprising a first pumping system for generating a fine vacuum connected to the lock chamber, and an additional pumping system for generating a high vacuum connected to the transfer chamber.

15. The lock system according to claim 12 wherein an end of the transfer chamber that adjoins the lock chamber comprises the passage, and a the cross-section of the passage presents a reduction in chamber cross-section, when viewed in the transport direction.

16. The lock system according to claim 12 further comprising aerating units connected to the lock chamber and the transfer chamber respectively, and optionally, one or both of the aerating units serve for aerating combined volume of the lock chamber and the transfer chamber.

17. The lock system according to claim 12 wherein a closing device of the lock gate of the lock chamber disposed on a side of the lock chamber that is oriented away from the transfer chamber is coupled to a closing device of the lock valve of the transfer chamber.

18. A vacuum-coating plant for coating flat substrates, the vacuum-coating plant comprising an inlet lock chamber, a process region and an outlet lock chamber disposed one after an other in a transport direction of a substrate, each lock chamber being separable from the process region and surrounding atmosphere in a vacuum-tight manner with aid of lock gates, the process region comprising at least one process chamber for treating the substrate, and a transfer chamber adjoining each lock chambers, further comprising at least one lock system as claimed in claim 12.
